(19) United States
(12) Patent Application Publication
(10) Pub. No.: US 2020/0203319 A1
(43) Pub. Date: Jun. 25, 2020

(54) MASS TRANSFER METHOD FOR MICRO LIGHT EMITTING DIODE AND LIGHT EMITTING PANEL MODULE USING THEREOF

(71) Applicant: J-METRICS TECHNOLOGY Co., Ltd., Taipei City (TW)

(72) Inventors: Hung-Ping LEE, Taipei City (TW); Yi-Hsiang CHIU, Taipei City (TW)

(21) Appl. No.: 16/460,782

(22) Filed: Jul. 2, 2019

(30) Foreign Application Priority Data
Dec. 20, 2018 (TW) 107146260

(51) Int. Cl. H01L 25/075; H01L 33/50; H01L 33/62

(52) U.S. Cl. CPC H01L 25/0753; H01L 33/502; H01L 2933/0041; H01L 2933/0066; H01L 33/62

(57) ABSTRACT

A mass transfer method for micro light emitting diode (LED) includes a micro-LED manufacturing step, a connecting step, a removing step, a fluorescent-powder layer forming step, and a filtering-sheet forming step. In the micro-LED manufacturing step, micro-LEDs are formed on a wafer substrate. Each micro-LED includes first and second electrodes. In the connecting step, the wafer substrate including the micro-LEDs is connected with a circuit substrate including first electrical-connection portions and second electrical-connection portions. Each first electrical-connection portion is connected to the first electrode of the corresponding micro-LED, and each second electrical-connection portion is connected to the second electrode of the corresponding micro-LED. In the removing step, the wafer substrate is removed. In the fluorescent-powder layer forming step, a fluorescent-powder layer is formed on the light-emitting surface of each of the micro-LEDs. In the filtering-sheet forming step, filtering-sheets are attached on the fluorescent-powder layer.

### CROSS-REFERENCE TO RELATED APPLICATION

This non-provisional application claims priority under 35 U.S.C. § 119(a) to Patent Application No. 107146260 in Taiwan, R.O.C. on Dec. 20, 2018, the entire contents of which are hereby incorporated by reference.

### BACKGROUND

### Technical Field

The instant disclosure relates to display technologies, in particular, to a mass transfer method for micro LED and a light emitting panel module using thereof.

### Related Art

Digital displays are utilized to different applications. In particular, liquid crystal displays (LCD) are the most popular displays. Regarding users demands, displays with are expected. However, though organic light-emitting diode (OLED) displays have advantages of high brightness and chromaticity, the lifetime for the OLED displays is limited. For example, after displays, mobile phones, or watches using OLED are used for a period (e.g., after 2000 hours), a screen burn-in phenomenon occurs frequently due to the intrinsic character of the OLED material.

LED may also have a higher brightness and chromaticity performance. However, problems of the size of the light source and the arrangements of the color blocks are to be solved firstly. Currently, the red light LEDs, the green light LEDs, and the blue light LEDs are manufactured individually and then transferred on the circuit board, for example, in a way of adhering. Nevertheless, in order to improve the resolution, the sizes of the LEDs are to be reduced. In the LED transfer method known to the inventor, the main drawback is that the arrangement precision for the LEDs cannot be improved. Moreover, in the case where the size of the LEDs are reduced, during cutting the LEDs from the wafer, the LEDs may be damaged or the electrical property of the LEDs may be affected, thereby decreasing the defect-free rate of the LED products.

### SUMMARY

In view of this, in one embodiment, a mass transfer method for micro light emitting diode (LED) is provided. The mass transfer method comprises a micro LED manufacturing step, a connecting step, a removing step, a fluorescent powder layer forming step, and a filtering sheet forming step. In the micro LED manufacturing step, a plurality of micro LEDs is formed on a wafer substrate. Each of the micro LEDs comprises a first electrode and a second electrode. In the connecting step, the wafer substrate comprising the micro LEDs is connected with a circuit substrate. The circuit substrate comprises a plurality of first electrical connection portions and a plurality of second electrical connection portions. Each of the first electrical connection portions is connected to the first electrode of the corresponding micro LED, and each of the second electrical connection portions is connected to the second electrode of the corresponding micro LED. In the removing step, the wafer substrate is removed. In the fluorescent powder layer forming step, a fluorescent powder layer is formed on the surface of each of the micro LEDs. In the filtering sheet forming step, a plurality of filtering sheets is attached on the fluorescent powder layer. Each of the filtering sheets corresponds to a light emitting surface.

In one or some embodiments, the micro LED manufacturing step comprises a doped semiconductor layer forming step, a patterning step, an insulation layer forming step, and an electrode forming step. In the doped semiconductor layer forming step, a first-type doped semiconductor material and a second-type doped semiconductor material layer are sequentially formed on the wafer substrate. In the patterning step, the first-type doped semiconductor material layer and the second-type doped semiconductor material layer are patterned to form a plurality of semiconductor patterns. Each of the semiconductor patterns has a first doped layer and a second doped layer, and a length of the second doped layer is less than a length of the first doped layer. In the insulation layer forming step, an insulation layer is formed on the first doped layer and the second doped layer. The insulation layer comprises a first via and a second via. The first via exposed a portion of the first doped layer, and the second via exposed a portion of the second doped layer. In the electrode forming step, the first electrode and the second electrode are formed on the insulation layer. A portion of the first electrode is filled in the first via and connected to the first doped layer. A portion of the second electrode is filled in the second via and connected to the second doped layer. The first electrode and the second electrode are separated from each other by the insulation layer.

Moreover, in one or some embodiments, the first electrode further shields a first side surface of the first doped layer, and the second electrode further shields the first doped layer and second side surfaces of the second doped layer. The second side surfaces are opposite to the first side surface.

In one or some embodiments, the light emitting surface is a surface of the wafer substrate disposing the first doped layer, and the light emitting surfaces of the micro LEDs are substantially at a same plane.

In one or some embodiments, the circuit substrate is an ASIC.

In one or some embodiments, the mass transfer method further comprises a chip connecting step. In the chip connecting step, a wired region of the circuit substrate is connected with an ASIC.

A light emitting panel module is also provided. The light emitting panel module comprises a circuit substrate, a plurality of micro LEDs, a fluorescent powder layer, and a plurality of filtering sheets. The circuit substrate comprises a plurality of first electrical connection portions and a plurality of second electrical connection portions. Each of the micro LEDs comprises a first doped layer, a second doped layer, a first electrode, and a second electrode. The first doped layer is stacked with the second doped layer. A first surface of the first doped layer is a light emitting surface, and a length of the first doped layer is greater than a length of the second doped layer. The first electrode is separated from the second electrode. Each of the first electrodes is connected to a connection surface of the first doped layer and a corresponding first electrical connection portion of the first electrical connection portions. Each of the second electrodes is connected to the second doped layer and a corresponding second electrical connection portion of the second electrical connection portions. The connection surface is opposite to the light emitting surface, and the light emitting surfaces of the micro LEDs are substantially at a same plane. The fluorescent powder layer is on the light emitting surface of each of the micro LEDs. The filtering sheets are on the fluorescent powder layer. Each of the filtering sheets corresponds to the light emitting surface of the corresponding micro LED.

In one or some embodiments, the first electrode and the second electrode are separated from each other by an insulation layer. Moreover, the first electrode further shields a first side surface of the first doped layer, the second electrode further shields the first doped layer and second side surfaces of the second doped layer, and the first side surface is opposite to the second side surfaces.

In one or some embodiments, the circuit substrate is an ASIC.

In one or some embodiments, the light emitting panel module further comprises an ASIC connected to a wired region of the circuit substrate.

In one or some embodiments, a length of each of the filtering sheets is greater than a length of the light emitting surface of the corresponding micro LED.

In the mass transfer method according to one or some embodiments of the instant disclosure, the micro LEDs on the wafer substrate are connected to the electrical connection portions of the circuit substrate to achieve the electrical connection between the micro LEDs and the circuit substrate. Then, the wafer substrate is removed. Under such arrangement, the transfer precision and the product defect-free rate can be improved greatly as well as having the advantages of fast product manufacture.

### BRIEF DESCRIPTION OF THE DRAWINGS

The disclosure will become more fully understood from the detailed description given herein below for illustration only, and thus not limitative of the disclosure, wherein:

FIG. 1 illustrates a flowchart of a mass transfer method for micro light emitting diode (LED) according to an exemplary embodiment of the instant disclosure;

FIGS. 2 to 10 illustrate sectional views showing steps corresponding to the mass transfer method for micro LED; and

FIG. 11 illustrates a sectional view of a light emitting panel module according to another embodiment of the instant disclosure.

### DETAILED DESCRIPTION

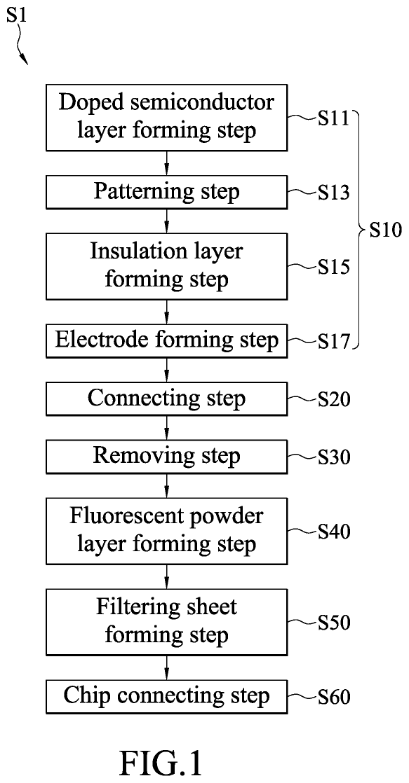

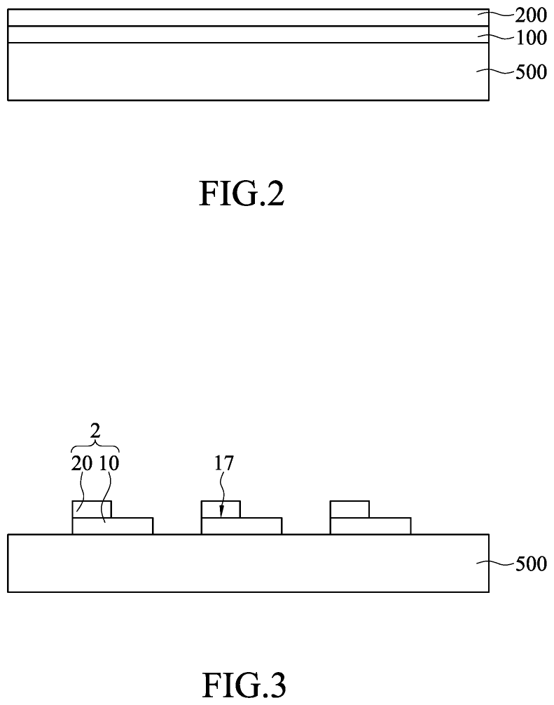

FIG. 1 illustrates a sectional view of a mass transfer method for micro light emitting diode (LED) according to an exemplary embodiment of the instant disclosure. FIGS. 2 to 10 illustrate sectional views showing steps corresponding to the mass transfer method for micro LED. As shown in FIG. 1, the mass transfer method S1 comprises a micro LED manufacturing step S10, a connecting step S20, a removing step S30, a fluorescent powder layer forming step S40, and a filtering sheet forming step S50.

In one or some embodiments, the micro LED manufacturing step S10 comprises a doped semiconductor layer forming step S11, a patterning step S13, an insulation layer forming step S15, and an electrode forming step S17. As shown in FIG. 2, in the doped semiconductor layer forming step S11, a first-type doped semiconductor material layer 100 and a second-type doped semiconductor material layer 200 are sequentially formed on the wafer substrate 500. For example, the wafer substrate 500 may be a sapphire wafer substrate, the first-type doped semiconductor material layer 100 may be an n-type doped semiconductor layer, and the second-type doped semiconductor material layer 200 may be a p-type doped semiconductor layer, embodiments are not limited thereto.

As shown in FIG. 3, in the patterning step S13, the first-type doped semiconductor material layer 100 and the second-type doped semiconductor material layer 200 are patterned to form a plurality of semiconductor patterns 2. Each of the semiconductor patterns 2 has a first doped layer 10 and a second doped layer 20. A length of the second doped layer 20 is less than a length of the first doped layer 10. In other words, by lithography, etching, or other ways, the first-type doped semiconductor material layer 100 may be patterned to form a plurality of first doped layers 10, and the second-type doped semiconductor material layer 200 may be patterned to form a plurality of second doped layers 20. In this embodiment, for each of the semiconductor patterns 2, a connection surface 17 between the first doped layer 10 and the second doped layer 20 forms a p-n junction.

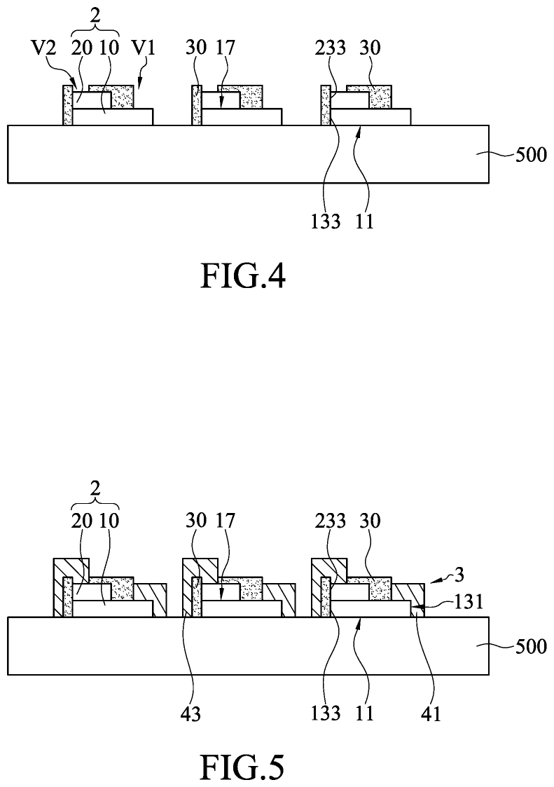

As shown in FIG. 4, in the insulation layer forming step S15, an insulation layer 30 is formed on the first doped layer 10 and on the second doped layer 20. The insulation layer 30 comprises a first via V1 and a second via V2. The first via V1 exposes a portion of the first doped layer 10, and the second via V2 exposes a portion of the second doped layer 20. In this embodiment, firstly an insulation material layer may be formed by roller-coating, and then the first via V1 and the second via V2 are formed on the insulation material layer using lithography or plasma etching techniques, so that the insulation layer 30 can be formed.

As shown in FIG. 5, in the electrode forming step S17, a first electrode 41 and a second electrode 43 are formed on the insulation layer 30. A portion of the first electrode 41 is filled in the first via V1 and connected to the first doped layer 10. A portion of the second electrode 43 is filled in the second via V2 and connected to the second doped layer 20. The first electrode 41 and the second electrode 43 are separated from each other by the insulation layer 30. Accordingly, a plurality of micro LEDs 3 can be formed on the wafer substrate 500. It is understood that, the foregoing steps are provided for illustrative purposes, and are not limitations for the embodiments of the instant disclosure. Methods for forming micro LED 3 on the wafer substrate 500 through the wafer manufacturing processes are applicable to be used in the micro LED manufacturing step S10.

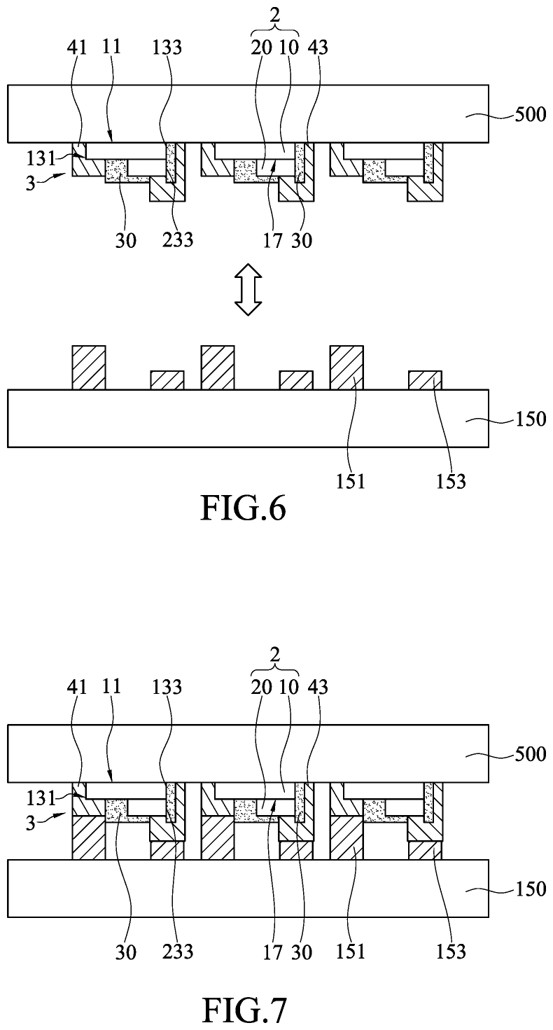

As shown in FIGS. 6 and 7, in the connecting step S20, the wafer substrate 500 comprising the micro LEDs 3 is connected with a circuit substrate 150. The circuit substrate 150 comprises a plurality of first electrical connection portions 151 and a plurality of second electrical connection portions 153. Each of the first electrical connection portions 151 is connected to the first electrode 41 of the corresponding micro LED 3, and each of the second electrical connection portions 153 is connected to the second electrode 43 of the corresponding micro LED 3. In this embodiment, the first electrical connection portions 151 and the second electrical connection portions 153 may be solder balls or bumps. The first electrical connection portions 151 and the second electrical connection portions 153 may have different heights, so that the first electrodes 41 and the second electrodes 43 can be respectively connected to the first electrical connection portions 141 and the second electrical connection portions 143 in a convenient manner, but embodiments are not limited thereto.

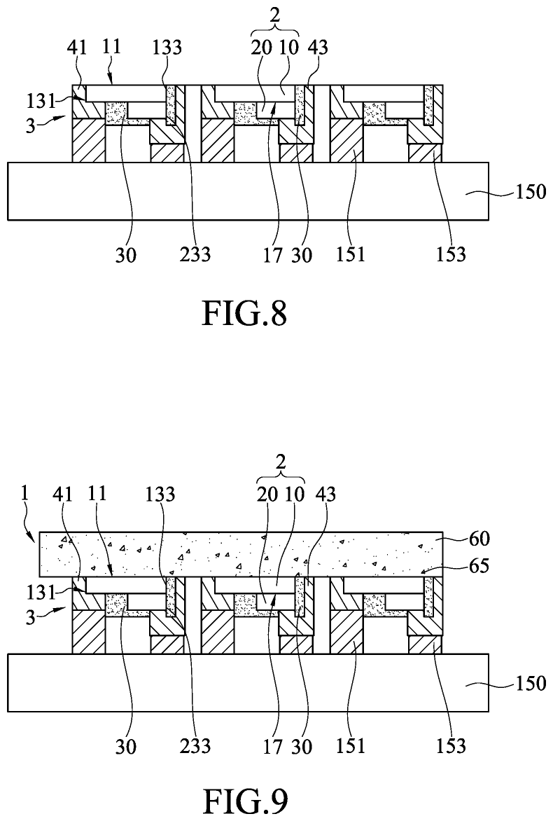

As shown in FIG. 8, in the removing step S30, the wafer substrate 500 is removed, so that a surface between the first doped layer 10 and the wafer substrate 500 becomes a light emitting surface 11 of the micro LED 3. In this embodiment, the light emitting surface 11 and the connection surface 17 are at opposite sides of the first doped layer 10. Moreover, since the first doped layer 10 is formed on the flat wafer substrate 500, the light emitting surfaces 11 of the micro LEDs 3 are substantially at a same plane after the wafer substrate 500 is removed. In this embodiment, the term substantially indicates that the light emitting surfaces 11 of the micro LEDs 3 are at the same plane in a macroscopic perspective, while tolerances generated during manufacturing processes in a microscopic perspective are allowed.

As shown in FIG. 9, in the fluorescent powder forming step S40, a fluorescent powder layer 60 is formed on the surface of each of the micro LEDs 3. In this embodiment, the micro LEDs 3 may be white light micro LEDs or blue light micro LEDs.

A plurality of fluorescent powders 65 in the fluorescent powder layer 60 can be excited by the light emitted from the light emitting surfaces 11 of the micro LEDs 3 to provide different light colors, so that the color gamut can be further expanded. In this embodiment, the fluorescent powder 65 may be quantum dots, but embodiments are not limited thereto.

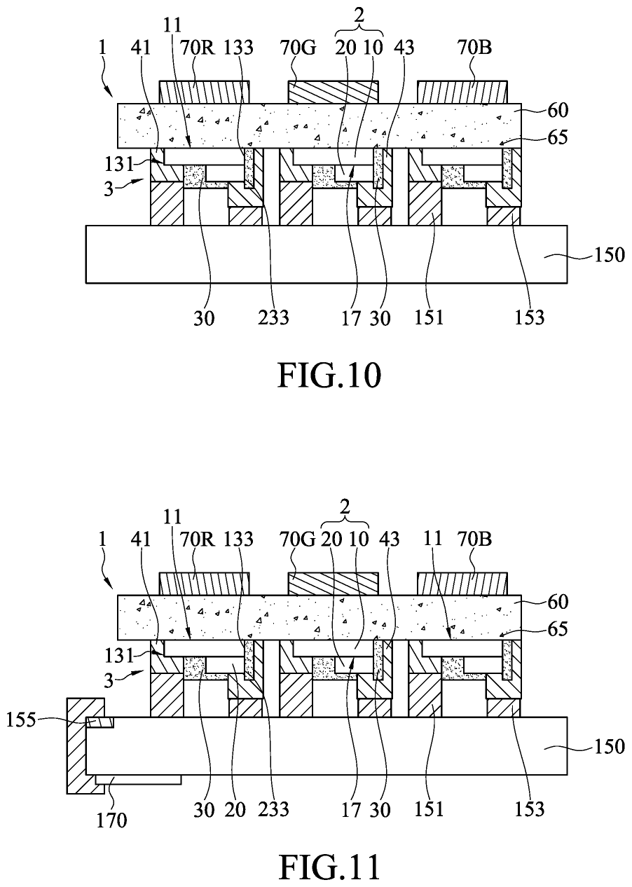

As shown in FIG. 10, in the filtering sheet forming step S50, a plurality of filtering sheets 70R, 70G, 70B is attached on the fluorescent powder layer 60. Each of the filtering sheets 70R, 70G, 70B corresponds to the light emitting surface 11 of each of the micro LEDs 3. As shown in the figure, the filtering sheet 70R is a red color filter, the filtering sheet 70G is a green color filter, and the filtering sheet 70B is a blue color filter, so that the micro LEDs 3 and the filtering sheets 70R, 70G, 70B can form pixels. In this embodiment, the order for the arrangement of the filtering sheets 70R, 70G, 70B is provided as an illustrative purpose, but not a limitation. According to the arrangement for the pixel, the filtering sheets 70R, 70G, 70B can be attached on certain locations of the micro LEDs 3 by different ways. In this embodiment, in the case where the micro LED 3 is a white light micro LED, the filtering sheet may not be required to be attached on the certain position of the white light micro LED 3, so that the brightness of the pixel can be improved. Accordingly, a light emitting panel module 1 can be manufactured. Moreover, the length of each of the filtering sheets 70R, 70G, 70B may be greater than the length of the light emitting surface 11 of the corresponding micro LED 3, so that light leakage can be prevented.

In this embodiment, the circuit substrate 150 may be an application specific integrated circuit (ASIC). Moreover, as shown in FIG. 10, the first electrode 41 further shields a first side surface 131 of the first doped layer 10, and the second electrode 43 further shields the first doped layer 10 and second side surfaces 133, 233 of the second doped layer 20. The first side surface 131 is opposite to the second side surfaces 133, 233. Because the first electrode 41 and the second electrode 43 are made of metal materials, the first electrode 41 and the second electrode 43 can be used for shielding lights and reflecting lights. Hence, the lights emitted from the first side surface 131 can be reflected by the first electrode 41 and directed toward the light emitting surface 11 and the lights emitted from the second side surfaces 133, 233 can be reflected by the second electrode 43 and directed toward the light emitting surface 11.

FIG. 11 illustrates a sectional view of a light emitting panel module according to another embodiment of the instant disclosure. Pease refer to FIGS. 1 and 11. The mass transfer method S1 may further comprise a chip connecting step S60. In the chip connecting step S60, a wired region 155 of the circuit substrate 150 is connected with an ASIC 170. Hence, the size of the ASIC 170 can be further reduced. In this embodiment, the positions of the wired region 155 and the ASIC 170 are provided for illustrative purposes, but not a limitation. Moreover, the chip connecting step S60 may be performed prior to the connecting step S20, and the chip connecting step S60 is not required to be performed as the last step of the mass transfer method S1.

As above, in the mass transfer method S1 according to one or some embodiments of the instant disclosure, the micro LEDs 3 on the wafer substrate 500 are connected to the electrical connection portions 151, 153 of the circuit substrate 150 to achieve the electrical connection between the micro LEDs 3 and the circuit substrate 150. Then, the wafer substrate 500 is removed. Under such arrangement, the method can be performed in a wafer scale perspective, and die cutting and glue transfer steps may not be required, thereby benefiting the advantages of high precision, high defect-free rate, and fast product manufacture.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A mass transfer method for micro light emitting diode (LED) comprising:
a micro LED manufacturing step: forming a plurality of micro LEDs on a wafer substrate, wherein each of the micro LEDs comprises a first electrode and a second electrode;
a connecting step: connecting the wafer substrate comprising the micro LEDs with a circuit substrate, wherein the circuit substrate comprises a plurality of first electrical connection portions and a plurality of second electrical connection portions; each of the first electrical connection portions is connected to the first electrode of the corresponding micro LED, and each of the second electrical connection portions is connected to the second electrode of the corresponding micro LED;
a removing step: removing the wafer substrate;
a fluorescent powder layer forming step: forming a fluorescent powder layer on a surface of each of the micro LEDs; and
a filtering sheet forming step: attaching a plurality of filtering sheets on the fluorescent powder layer, wherein each of the filtering sheets corresponds to a light emitting surface of the corresponding micro LED.

2. The mass transfer method for micro LED according to claim 1, wherein the micro LED manufacturing step comprises:
a doped semiconductor layer forming step: sequentially forming a first-type doped semiconductor material layer and a second-type doped semiconductor material layer on the wafer substrate;
a patterning step: patterning the first-type doped semiconductor material layer and the second-type doped semiconductor material layer to form a plurality of semiconductor patterns, wherein each of the semiconductor patterns has a first doped layer and a second doped layer, and a length of the second doped layer is less than a length of the first doped layer;
an insulation layer forming step: forming an insulation layer on the first doped layer and on the second doped layer, wherein the insulation layer comprises a first via and a second via, the first via exposes a portion of the first doped layer, and the second via exposes a portion of the second doped layer; and
an electrode forming step: forming the first electrode and the second electrode on the insulation layer, wherein a portion of the first electrode is filled in the first via and connected to the first doped layer, a portion of the second electrode is filled in the second via and connected to the second doped layer; the first electrode and the second electrode are separated from each other by the insulation layer.

3. The mass transfer method for micro LED according to claim 2, wherein the first electrode further shields a first side surface of the first doped layer, the second electrode further shields the first doped layer and second side surfaces of the second doped layer, and the second side surfaces are opposite to the first side surface.

4. The mass transfer method according to claim 2, wherein the light emitting surface is a surface of the wafer substrate disposing the first doped layer, and the light emitting surfaces of the micro LEDs are substantially at a same plane.

5. The mass transfer method according to claim 1, wherein the circuit substrate is an ASIC.

6. The mass transfer method according to claim 1, further comprising a chip connecting step: connecting a wired region of the circuit substrate with an ASIC.

7. A light emitting panel module, comprising:
a circuit substrate comprising a plurality of first electrical connection portions and a plurality of second electrical connection portions;
a plurality of micro LEDs each comprises a first doped layer, a second doped layer, a first electrode, and a second electrode, wherein the first doped layer is stacked with the second doped layer; a first surface of the first doped layer is a light emitting surface; a length of the first doped layer is greater than a length of the second doped layer; the first electrode is separated from the second electrode; each of the first electrodes is connected to a connection surface of the first doped layer and a corresponding first electrical connection portion of the first electrical connection portions, and each of the second electrodes is connected to the second doped layer and a corresponding second electrical connection portion of the second electrical connection portions; the connection surface is opposite to the light emitting surface, and the light emitting surfaces of the micro LEDs are substantially at a same plane;
a fluorescent powder layer on the light emitting surface of each of the micro LEDs; and
a plurality of filtering sheets on the fluorescent powder layer, wherein each of the filtering sheets corresponds to the light emitting surface of the corresponding micro LED.

8. The light emitting panel module according to claim 7, wherein the first electrode and the second electrode are separated from each other by an insulation layer.

9. The light emitting panel module according to claim 8, wherein the first electrode further shields a first side surface of the first doped layer, the second electrode further shields the first doped layer and second side surfaces of the second doped layer, and the first side surface is opposite to the second side surfaces.

10. The light emitting panel module according to claim 7, wherein the circuit substrate is an ASIC.

11. The light emitting panel module according to claim 7, further comprising an ASIC connected to a wired region of the circuit substrate.

12. The light emitting panel module according to claim 7, wherein a length of each of the filtering sheets is greater than a length of the light emitting surface of the corresponding micro LED.
